(19) United States
(12) Patent Application Publication
(10) Pub. No.: US 2010/0264518 A1
(43) Pub. Date: Oct. 21, 2010

(54) WAFER AND METHOD FOR CONSTRUCTION, STRENGTHENING AND HOMOGENIZATION THEREOF

(76) Inventor: Shura LEE, Hsinchu City (TW)

Correspondence Address: EGBERT LAW OFFICES, 412 MAIN STREET, 7TH FLOOR, HOUSTON, TX, 77002, US

(21) Appl. No.: 12/423,969

(22) Filed: Apr. 15, 2009

(51) Int. Cl. H01L 29/02; H01L 21/304; H01L 21/306

(52) U.S. Cl. 257/618; 438/463; 438/691; 257/E21.237; 257/E21.219; 257/E29.002

(57) ABSTRACT

The present invention provides a water and a method for strengthening, homogenization and construction thereof. The concave and convex portions are processed by laser or etching, and then formed at intervals on the grinding surface of the wafer. The concave and convex portions are round or polygonal shapes. With the alternated arrangement of the concave and convex portions, a mesh structure of consistent construction is formed on the grinding surface of the wafer, making it possible to cut down greatly the interference and influence generated by the texture of grinding surface, and improve substantially the structural strength of the grinding surface for a consistent quality of wafer with better applicability and industrial benefits.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

1. Field of the Invention

The present invention relates generally to a strengthening and homogenization method for construction of a wafer, and more particularly to an innovative method for constructing a wafer with a concave or convex portion at intervals on the grinding surface of the wafer.

2. Description of Related Art Including Information Disclosed Under 37 CFR 1.97 and 37 CFR 1.98.

A wafer is typically used as a substrate in a semiconductor. Referring to FIG. 1, the wafer must be first cut into a flaky wafer 10 after molding (shown in FIG. 1(a)), then the flaky wafer 10 is ground and leveled to form a grinding surface 11 (shown in FIG. 1(b)). Next, the flaky wafer 10 is cut into a chip substrate 12 (shown in FIG. 1(c)), necessary for semiconductor products. Yet, spin-like grinding lines will be shaped on the grinding surface 11 of flaky wafer 10 due to the grinding and leveling operation. For a fine chip substrate 12, such lines will lead to a coarse texture 13 on the grinding surface 11 (shown in FIG. 1(d)), and different textures 13 of every chip substrate 12 cut through a single flaky wafer 10 will affect the consistency of strength and quality of finished chips. Referring to FIGS. 2 and 3, when force f is applied to various chip substrates 12, 12b under the same direction, axial line and position, the texture 13 interlaced with the force will be subject to stronger stress, and that in parallel with the force f, will be subject to smaller stress due to different directions of textures 13, 13b of the chip substrates 12, 12b. Hence, this causes inconsistent stress (12b 12). This case proves that, the conventional chip substrates from the same flaky wafer are subject to the influence of the surface texture, making it difficult to control quality and consistency.

Thus, to overcome the aforementioned problems of the prior art, it would be an advancement in the art to provide an improved structure that can significantly improve efficacy.

Therefore, the inventor has provided the present invention of practicability after deliberate design and evaluation based on years of experience in the production, development and design of related products.

### BRIEF SUMMARY OF THE INVENTION

Based on the alternated arrangement of concave or convex of the “strengthening and leveling method of the wafer of the present invention, a mesh structure of consistent construction is formed on the grinding surface of the wafer, making it possible to cut down greatly the influences generated by the texture of a grinding surface. The structural strength of the grinding surface is significantly improved for a consistent quality of wafer with better applicability and industrial benefits.

Although the invention has been explained in relation to its preferred embodiment, it is to be understood that many other possible modifications and variations can be made without departing from the spirit and scope of the invention as hereinafter claimed.

### BRIEF DESCRIPTION OF THE SEVERAL VIEWS OF THE DRAWINGS

FIG. 1 shows a schematic view of processing of a prior art wafer.

FIG. 2 shows a schematic view of a force first applied to a typical prior art chip substrate.

FIG. 3 shows a schematic view of a force subsequently applied to a typical prior art chip substrate.

FIG. 4 shows a schematic view of processing of the wafer of the present invention.

FIG. 5 shows a top plan view of the preferred embodiment of the wafer of the present invention, being concave.

FIG. 6 shows an enlarged sectional view of the wafer of FIG. 5.

FIG. 7 shows a top plan view of another preferred embodiment of the wafer of the present invention.

FIG. 8 shows a top plan view of still another preferred embodiment of the wafer of the present invention.

FIG. 9 shows a schematic view of a preferred embodiment of the cross section of the wafer of the present invention.

FIG. 10 shows another schematic view of another preferred embodiment of the cross section of the wafer of the present invention.

FIG. 11 shows a graph illustration, comparing the cutting quality of the present invention and the typical prior art wafer.

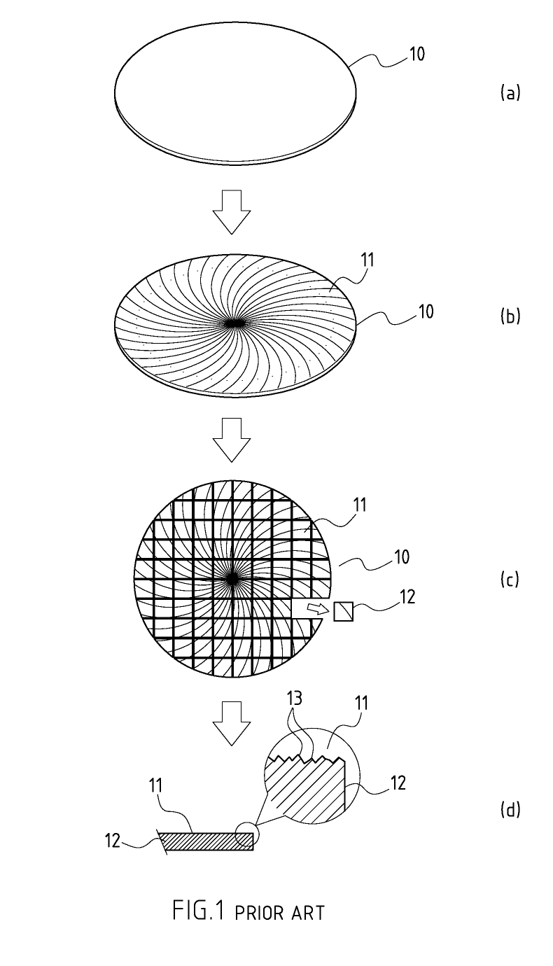

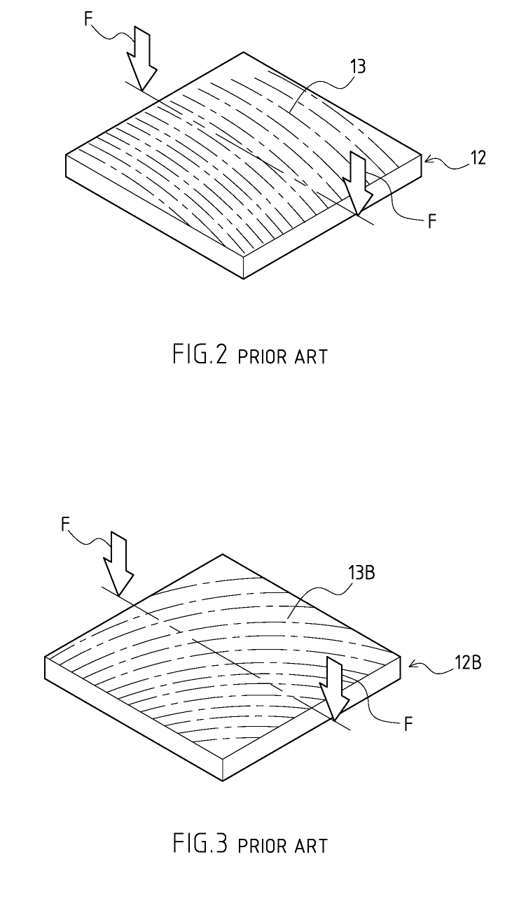

### DETAILED DESCRIPTION OF THE INVENTION

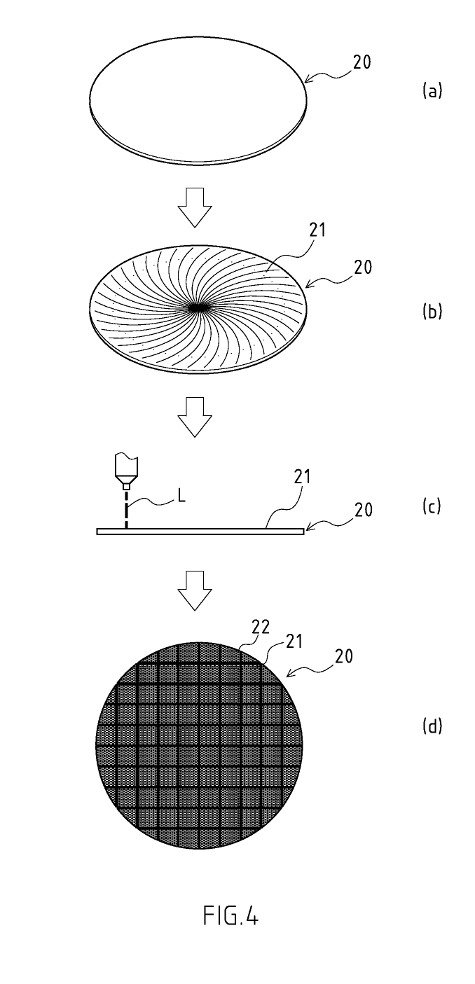

FIGS. 4 depicts a preferred embodiment of strengthening and homogenization method for construction of a wafer of the present invention. The embodiments are provided for only explanatory objectives with respect to the patent claims.

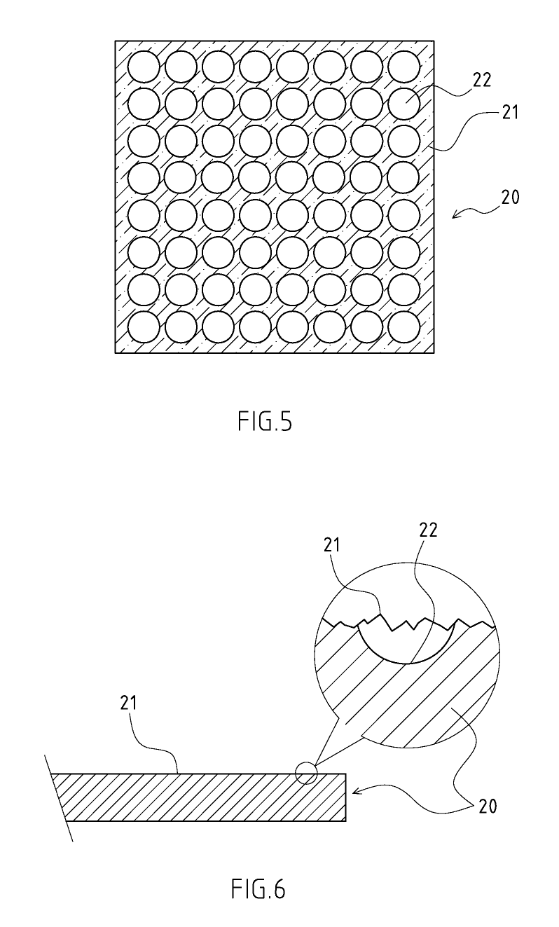

The strengthening and leveling method of the wafer is concerned with the wafer already cut into flaky shapes. According to this method, a wafer 20 is ground into a grinding surface 21 (shown in FIG. 4(a), (b)), then a concave 22 or convex is processed, e.g. by means of a laser, and then shaped at intervals on the entire grinding surface 21 of the wafer 20. Referring to FIG. 4(c), the grinding surface 21 of the wafer 20 can be processed into the concaves 22 of preset depth (shown in FIG. 6) by means of laser beam 1. As the concaves 22 are arranged at intervals, a mesh structure of consistent depth is formed on the grinding surface 21 of the wafer 20, making it possible to cut down greatly the influences generated by the texture of grinding surface 21, and improve substantially the structural strength of the grinding surface 21 for a consistent quality of wafer 20. Alternatively, convex protrusions can also be shaped at intervals by the same laser method.

The concave or convex portion can be shaped at interval by means of an etching method.

Referring to FIG. 4, a concave 22 or convex portion is cut after being processed and formed at interval on the grinding surface 21 of the wafer 20 (shown in FIG. 4(d)), then the wafer 20 is cut into a predefined chip substrate. Alternatively, the wafer 20 is first cut, and then a concave 22 or convex portion is formed at intervals on the grinding surface of the wafer; so the processing methods are not limited to the wafer cutting procedure.

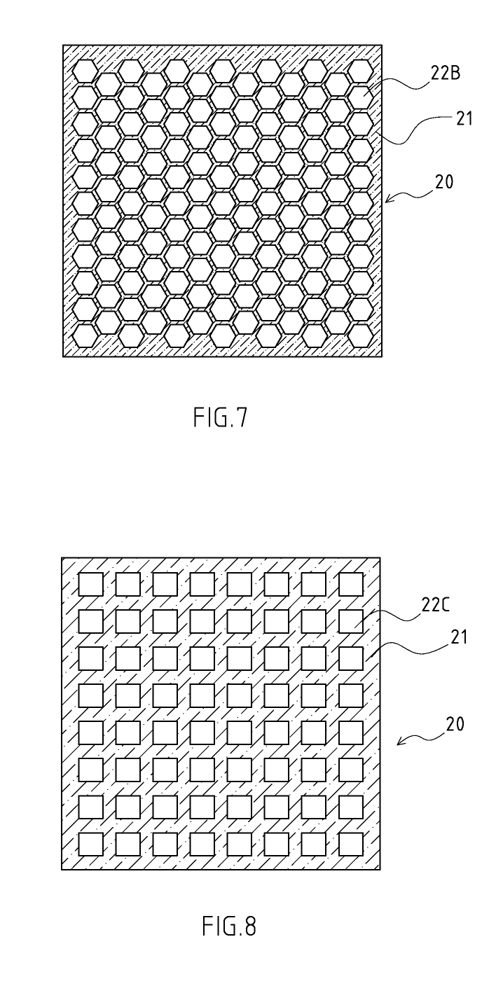

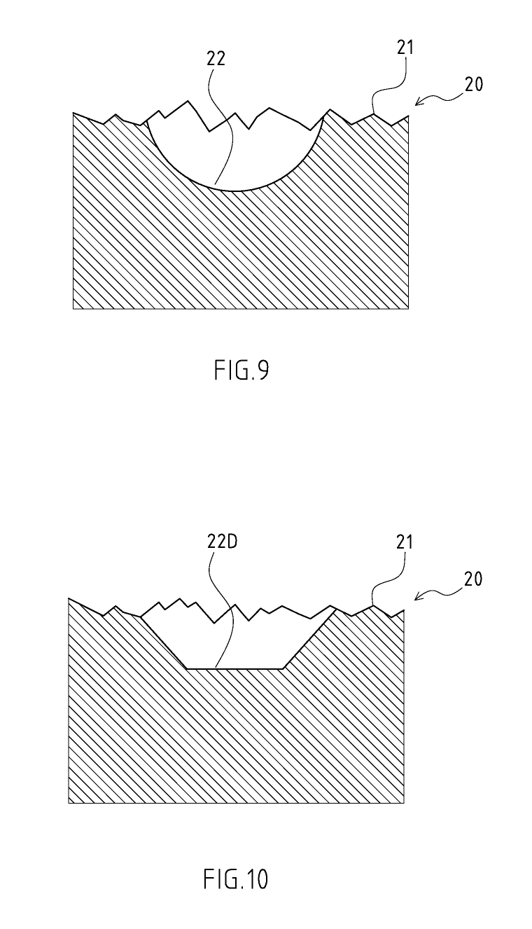

Other than the round shape of concave 22 (or convex) as shown in FIG. 5, the concave 22b can also be of a hexagon as shown in FIG. 7; or the concave 22c can also be of a quadrangle as shown in FIG. 8.

The profile of the concave 22 can be designed into a curved dent as shown in FIG. 9, or the profile of the concave 22d can also be designed into a trapezoid dent as shown in FIG. 10, or pyramidal or depressed recesses, etc.

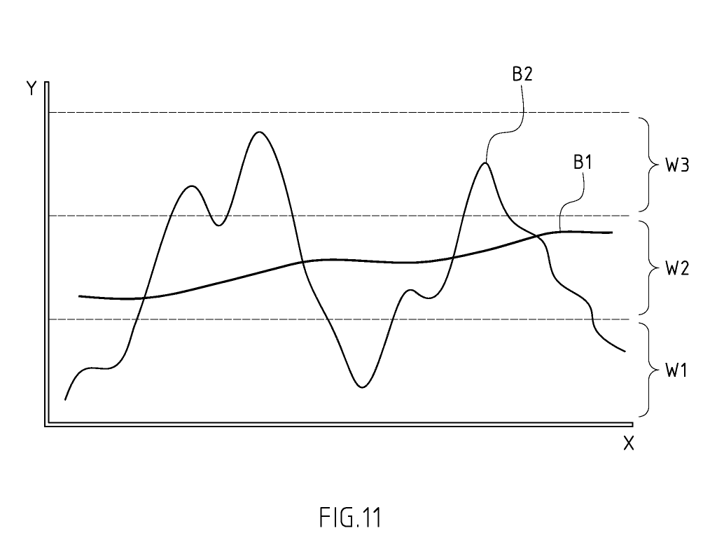

Additionally, with alternated arrangement of concave or convex, the strengthening, homogenization method of the wafer and its construction of the present invention enable provision of chips of consistent strength and quality. FIG. 11 depicts a comparison diagram of the cutting quality between the present invention and typical wafer, wherein axis-y represents the strength of wafer, axis-x represents the number of chips cut from a single wafer, and curve b I represents the cutting quality of the wafer of the present invention. The strength of the chips cut from the same wafer can be controlled within a smaller clearance (as shown in w2), and the strength of chips cut from typical wafer (shown by curve b2) is irregular and inconsistent (as shown in w1, w2, w3).

1. A method for strengthening and homogenization of a wafer, comprising the steps of:
cutting to form a flaky wafer with a grinding surface;
processing and shaping concave and convex on portions of said grinding surface at intervals, said grinding surface of the wafer having levelness set by the portions.

2. The method defined in claim 1, wherein the step of processing is implemented by laser.

3. The method defined in claim 1, wherein the step of processing is implemented by etching.

4. The method defined in claim 1, wherein a the step of processing and shaping the concave and convex portions is further comprised of cutting off.

5. The method defined in claim 1, wherein the step of cutting to form the wafer is before the step of processing and shaping concave and convex portions.

6. The method defined in claim 1, wherein the step of processing and shaping the concave and convex portions is in a mesh shape.

7. A strengthened and homogenized wafer, comprising:
a wafer body with a grinding surface; and
concave and convex portions arranged at intervals on said grinding surface, said grinding surface having levelness.

8. The wafer defined in claim 7, wherein the concave and convex portions have a cross-section being round or polygonal or a combination.

9. The wafer defined in claim 7, wherein the concave portions are formed as a curved dent, or a trapezoid, pyramidal or depressed recess or any combination thereof.

10. The wafer defined in claim 7, wherein the concave and convex portions are arranged at intervals on the entire grinding surface of the wafer in a mesh shape.
